(19) United States
(12) Patent Application Publication
(10) Pub. No.: US 2025/0072152 A1
(43) Pub. Date: Feb. 27, 2025

(54) Semiconductor X-Ray Detector with Light Emitting Layer and Method Therefor

(71) Applicant: Carl Zeiss X Ray Microscopy Inc., Dublin, CA (US)

(72) Inventors: Philipp Brenner, Karlsruhe (DE); Xiaochao Xu, Dublin, CA (US)

(21) Appl. No.: 18/722,209

(22) PCT Filed: Jan. 6, 2023
(86) PCT No.: PCT/US2023/060214

§ 371 Date: Jun. 20, 2024

Related U.S. Application Data
(60) Provisional application No. 63/297,572, filed on Jan. 7, 2022.

(51) Int. Cl. H01L 31/12; G01T 1/24

(52) U.S. Cl. CPC H01L 31/125; G01T 1/24

(57) ABSTRACT

A detection system comprises a semiconductor layer for converting photons or particles into charge carriers and a light emitting layer for generating light from the charge carriers. This can be used for the detection of x-rays or charged particles. The semiconductor layer can include amorphous selenium (a-Se), GaAs, CdZnTe, CdTe or perovskite semiconductors. The light emitting layer might be an organic light emitting diode (OLED), GaAs AlGaAs, InGaAs or perovskite semiconductors. Other possibilities are CdTe or CdZnTe. In addition, useful methods to increase light outcoupling out of the light emission layer are described.

### RELATED APPLICATIONS

This application claims the benefit under 35 USC 119 (e) of U.S. Provisional Application No. 63/297,572, filed on Jan. 7, 2022, which is incorporated herein by reference in its entirety.

### BACKGROUND OF THE INVENTION

X-ray microscopy and other applications require high spatial resolution and high efficiency detection of x-rays or high energy particles.

Some current x-ray microscopes utilize optical coupling of a thin scintillator detector to a charge coupled device (CCD) or complementary metal oxide semiconductor (CMOS) camera via an optical microscope. This setup enables high-resolution imaging.

The optical coupling in scintillator-optical microscope-camera detection systems is not perfect, however. The light collection efficiency is limited because of the finite objective numerical aperture (NA) and light loss in the optical microscope. This results in a reduction in Detective Quantum Efficiency (DQE) for the x-ray detection (the so-called quantum sink) and the direct consequence is a reduction in the imaging throughput.

Another option for detecting x-rays or high energy particle beams utilizes semiconductor direct conversion detection materials. The x-rays or particles create free charge carriers that are directed to a spatial light modulator, such as a liquid crystal (LC) light valve. The electrical charge of the carriers modulate the light valve, which is then illuminated by an external light source of an optical microscope.

### SUMMARY OF THE INVENTION

The present invention concerns an x-ray or other high energy particle detector. Charge carriers are created in an absorption process and these carriers are transferred by an electric field to a light emitting layer, like a light emitting diode (LED), where effective recombination takes place.

In general, according to one aspect, the invention features a detection system comprising a semiconductor layer for converting photons or particles into charge carriers and a light emitting layer for generating light from the charge carriers.

In embodiments, the semiconductor layer coverts x-rays into the charge carriers.

The semiconductor layer might include amorphous selenium (a-Se), GaAs, CdZnTe, or CdTe or perovskite semiconductors containing high atomic number elements.

In addition, the light emitting layer might be an organic light emitting diode (OLED) or include GaAs AlGaAs or InGaAs.

In other cases, the light emitting layer might be CdTe or CdZnTe, or one of the perovskite semiconductors.

In one further change, a reflective layer is used between the semiconductor layer and the light emitting layer wherein the semiconductor layer coverts x-rays into the charge carriers.

Other options include other layers or structures including a reflective layer, a Bragg grating, a surface structure, and/or microlens between the semiconductor layer and the light emitting layer to improve light to the detector or camera.

In general, according to another aspect, the invention features a detection method, comprising converting photons or particles into charge carriers in a semiconductor layer and generating light from the charge carriers.

In general, according to another aspect, the invention features an x-ray microscopy system. It comprises an x-ray source for generating an x-ray beam, an object holder for holding an object in the x-ray beam, and an x-ray detection system. This detection system has a detector comprising a semiconductor layer for converting x-rays from the x-ray beam into charge carriers and a light emitting layer for generating light from the charge carriers. This light is then detected with a camera.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIGS. 1A and 1B are a side view showing a semiconductor light emitting diode (LED) x-ray detector of the present invention according to two embodiments;

FIG. 2 is a side schematic perspective view showing the layers of an embodiment of the semiconductor LED x-ray detector;

FIG. 3 shows a simulated GaAs detector/LED device band diagram at a forward bias of V=5 V; E_{c} is the conduction band, Eᵥ valence band; E_{fn} is the quasi-Fermi level of electrons and E_{fp} is the quasi-Fermi level of holes; and the right diagram is a blow up of the LED section of the device;

FIG. 4A shows the simulated electron and hole concentrations of the GaAs detector/LED device at forward bias of 5V as a function of distance; and FIG. 4B shows simulated rates of various carrier recombination processes near the active QW region as function of distance;

FIG. 5 is a plot of IQE at different bias voltages for the simulated GaAs detector/LED device;

FIG. 6 shows the GaAs Detector/LED simulated rates at forward bias of V=5 V with illumination at z=0; The right plot is a blow up around the active QW region of the device; the light intensity corresponds to relative light intensity of 0.1 as in FIGS. 7A and 7B;

FIG. 7A is a simulated total current output of the GaAs detector/LED device with different light intensity at forward bias of 5 V. FIG. 7B is a simulated IQE of the GaAs detector/LED device with different light intensity at forward bias of 5 V;

FIG. 8 is a schematic side view showing the layers of an embodiment of the semiconductor LED x-ray detector;

FIG. 9 shows the simulated CdTe detector/LED device band diagram at forward bias V=5 V. E_{c} is the conduction band, Eᵥ valence band. E_{fn} is the quasi-Fermi level of electrons and E_{fp} is the quasi-Fermi level of holes, the right diagram is a blow up of the LED section of the device;

FIG. 10A shows the simulated electron and hole concentrations of the CdTe detector/LED device at forward bias of 5 V as a function of distance; and FIG. 10B shows simulated rates of various carrier recombination processes near the active QW region as function of distance;

FIG. 11 shows the CdTe Detector/LED simulated rates at forward bias of V=5 V with illumination at z=0, the right diagram is a blow up around the active QW region of the device, the light intensity corresponds to relative light intensity of 0.1 as in FIGS. 12A and 12B;

FIG. 12A shows the simulated total current output of the CdTe detector/LED device with different light intensity at forward bias of 5 V; and FIG. 12B shows the simulated IQE of the CdTe detector/LED device with different light intensity at forward bias of 5 V;

FIG. 13 is a schematic side view of a semiconductor light emitting x-ray detector using a perovskite semiconductor and an OLED;

FIG. 14 shows the semiconductor LED x-ray detector with its optical readout;

FIG. 15 is a schematic diagram of an x-ray microscope to which the present invention is applicable.

### DETAILED DESCRIPTION OF THE PREFERRED EMBODIMENTS

The invention now will be described more fully hereinafter with reference to the accompanying drawings, in which illustrative embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

As used herein, the term “and/or” includes any and all combinations of one or more of the associated listed items. Also, all conjunctions used are to be understood in the most inclusive sense possible. Thus, the word “or” should be understood as having the definition of a logical “or” rather than that of a logical “exclusive or” unless the context clearly necessitates otherwise. Further, the singular forms and the articles “a”, “an” and “the” are intended to include the plural forms as well, unless expressly stated otherwise. It will be further understood that the terms: includes, comprises, including and/or comprising, when used in this specification, specify the presence of stated features, integers, steps, operations, elements, and/or components, but do not preclude the presence or addition of one or more other features, integers, steps, operations, elements, components, and/or groups thereof. Further, it will be understood that when an element, including component or subsystem, is referred to and/or shown as being connected or coupled to another element, it can be directly connected or coupled to the other element or intervening elements may be present.

It will be understood that although terms such as “first” and “second” are used herein to describe various elements, these elements should not be limited by these terms. These terms are only used to distinguish one element from another element. Thus, an element discussed below could be termed a second element, and similarly, a second element may be termed a first element without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The present invention concerns an x-ray detector architecture. One charge carrier type of the created electron-hole pairs in the absorption process is transferred by an electric field to a thin light emitting zone, where effective recombination takes place. The emission zone hereby is characterized by a thickness that is comparable or less than the depth-of-field of high NA-objectives. The thickness of the absorbing layer can be significantly increased compared to direct scintillation approaches, thus allowing an improved DQE. The device can be generally thought of as a directly/monolithically connected direct X-ray absorber and light emitting diode (LED).

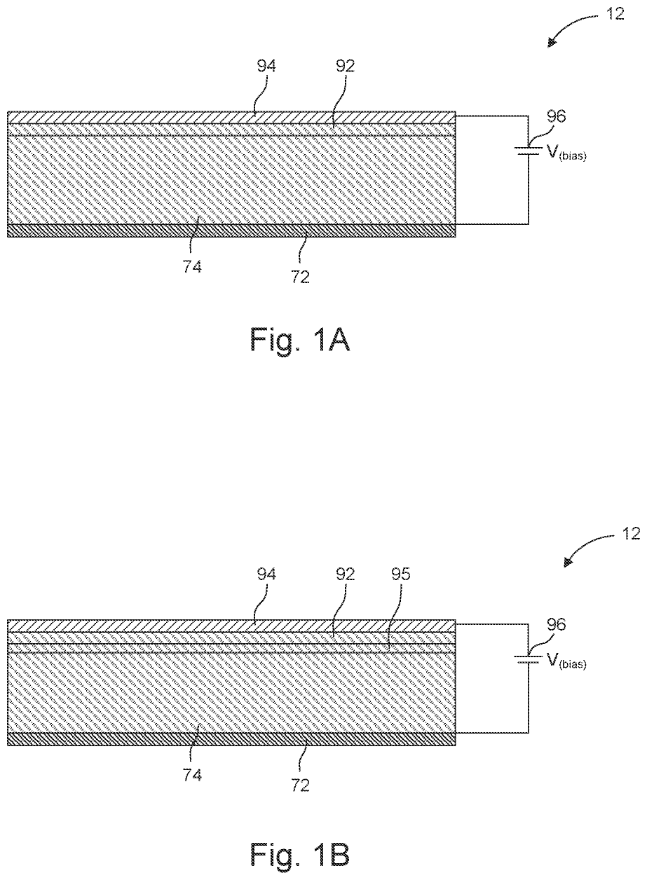

FIG. 1A shows the basic arrangement of semiconductor light emitting diode (LED) x-ray detector 12 that has been constructed according to the principles of the present invention.

The detector 12 comprises LED layer 92 disposed on one side of a semiconductor detector layer 74. An x-ray-side electrode layer 72 is deposited on an x-ray side of the semiconductor detector layer 74. On an optical-side of the semiconductor detector layer 74 is the LED layer 92 followed by an optical-side electrode layer 94 such as a transparent Indium Tin Oxide (ITO).

The layer 74 is generally a semiconductor having a relatively high effective atomic number Z and density to effectively stop and absorb the x-ray radiation. The electrical resistivity should be high with a value of around or larger than 10⁶ Ωcm to reduce the dark current. In addition, at least one type of the excited charge carriers (electrons or holes) can be transported through the thickness of the semiconductor layer 74 before it recombines in the absorption layer, i.e. the excited charge carrier that is used for injection into the LED layer 92 has a relatively high mobility-lifetime product μτ. Other requirements are similar to those required with other semiconductor x-ray detectors, such as low polarization and stability over time and other conditions.

The semiconductor layer 74 will often have a thickness in the range of about a few micrometers (such as between 2 and 5 micrometers) to 1 mm. In some examples, this layer is amorphous selenium (a-Se), GaAs, CdZnTe, CdTe, or perovskite semiconductor crystal (ABX3). Other options are perovskite semiconductor materials containing high atomic number elements, and other similar materials.

The working mechanism is as follows. A charge cloud (cloud of electron-hole pairs) is created within the thick semiconductor layer 74 by absorption of the x-ray photon or particle. The electron and holes travel in opposite directions due to the applied electric field though the x-ray-side electrode layer 72 and the optical-side electrode layer 94 by bias voltage source 96. One of the charge carrier types is injected into a thin emission zone of the LED layer 92. Its structure is tailored for effective radiative recombination. The radiative recombination results in the emission of a photon, which propagates through the optical-side electrode layer 94 and can then be detected in a similar manner like a thin scintillator. The light emitting layer 92 could be an inorganic or organic LED.

An important requirement for the LED layer 92 is that it operates efficiently over a wide range of charge carriers that are injected into the layer. The amount of charge carriers injected depends on the amount of absorbed X-ray photons and thus varies throughout operation. Special layer stacks and growth conditions must be considered in order to ensure efficient operation at low charge carrier injection densities.

Advantages exist when organic light emitting diode (OLED) layer is used for the LED layer 92. OLEDs exhibit high efficiencies at low charge carrier injection densities while an efficiency roll-off is usually observed at high charge injection densities. Another advantage of using an OLED is that the layers can be deposited by thermal evaporation on different absorber substrates as no lattice matching has to be taken into account as it is the case for epitaxial techniques which must be applied for inorganic semiconductors.

In one embodiment, the detector 12 uses a GaAs based semiconductor detector absorber layer 74. For the LED layer 92, its related alloys, AlGaAs and InGaAs are used to form a heterostructure. One advantage of GaAs is that it has one of the largest radiative recombination rates among commonly available semiconductor materials. In addition, because of its wide availability, the technologies for making such LEDs are mature and easily available.

The LED based detector will cover a wide range of x-ray flux levels, when the flux level is low, or for single photon detection, the x-ray generated current in the detector is rather small. A typical LED has a rather low light efficiency when the driving current is low because non-radiative recombination overtakes radiative recombination at low charge injection rate.

In one example, the LED layer 92 is designed for high efficiency at ultra-low current to overcome the shortcomings of regular LEDs that designed to work at higher injection currents. A single quantum well (QW) is used with a specially designed well and cladding, in one embodiment. The improvements are achieved via two mechanisms: (1) a high-quality InGaAs/InGaP or GaAs/InGaP interface reduces the interface recombination velocity (IRV) and (2) large valence band offset Qᵥ=ΔEᵥ/(ΔEᵥ+ΔE_{c}) to make hole density p much larger than electron density n within the QW (or large conduction band offset Q_{c}=ΔE_{c}/(ΔEᵥ+ΔE_{c}) to make electron density n much larger than hole density p within the QW).

In another example, the LED layer 92 has a InGaP/GaAs/InGaP double heterojunction, which have been demonstrated for high quantum efficiency. In one specific example, the InGaP band gap is 1.90 eV, and the InGaP/GaAs conduction band offset is 0.10 eV and valence band offset 0.38 eV.

FIG. 1B shows another embodiment that adds a light reflecting layer such as a Bragg distributed reflector layers.

In more detail, it should be noted that half of the light from the active layer of the LED layer 92 goes toward the semiconductor layer 74 instead of the optical-side electrode layer 94. Thus, to further increase the output of the light, a distributed Bragg reflector (DBR) or other light reflecting layer 95 is added between the LED layer 92 and the semiconductor layer 74 to reflect most of the light towards the optical-side electrode layer 94 and the output aperture. This is similar to the DBRs in vertical-cavity surface-emitting lasers (VCSEL) for example.

In addition, to further shape the wavefront of the emission light, a dielectric material can be deposited onto the output window, or the transparent electrode can be patterned. Potentially, the shaped wavefront together with the collection optics can improve the light collection efficiency. In addition, antireflective (AR) layers and/or metalenses can be added.

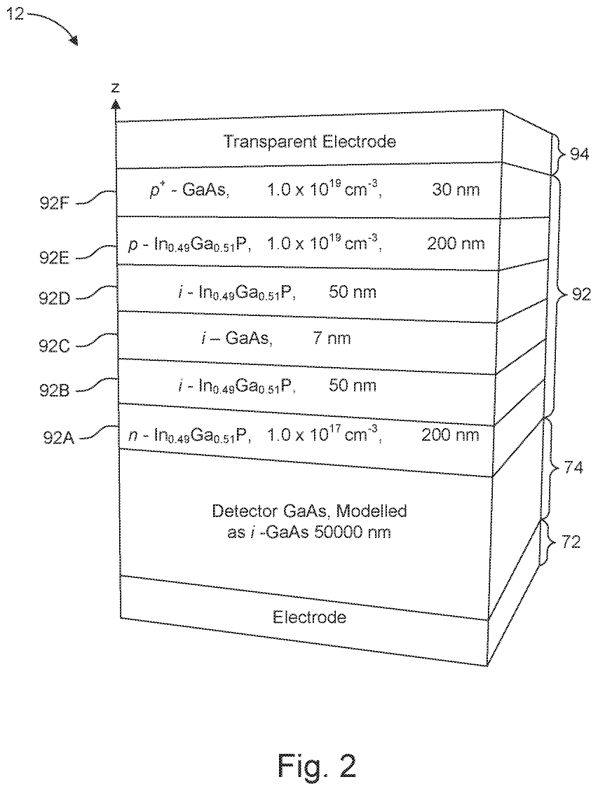

FIG. 2 shows show one specific embodiment of the detector 12.

The semiconductor detector absorber layer 74 is a thick GaAs layer for detecting x-ray. The thick GaAs layer will be over 100 microns thick and preferable 200 microns thick or more. (Note, however, for simulation purposes, a thickness of 5 μm was used.) It is located on the x-ray-side electrode layer 72. The LED heterostructure layer 92 includes an n type In_{0.49}Ga_{0.51}P contact layer 92A of 200 nanometers (nm), followed by an In_{0.49}Ga_{0.51}P layer 92B of 50 nm, a GaAs layer 92C layer of 7 nm, and another In_{0.49}Ga_{0.51}P layer 92D of 50 nanometers to form a double heterojunction. A p type In_{0.49}Ga_{0.51}As hole contact layer 92E of 200 nm thickness and a p+ GaAs hole contact layer 92F of 30 nm thickness are used before the optical-side electrode layer 94.

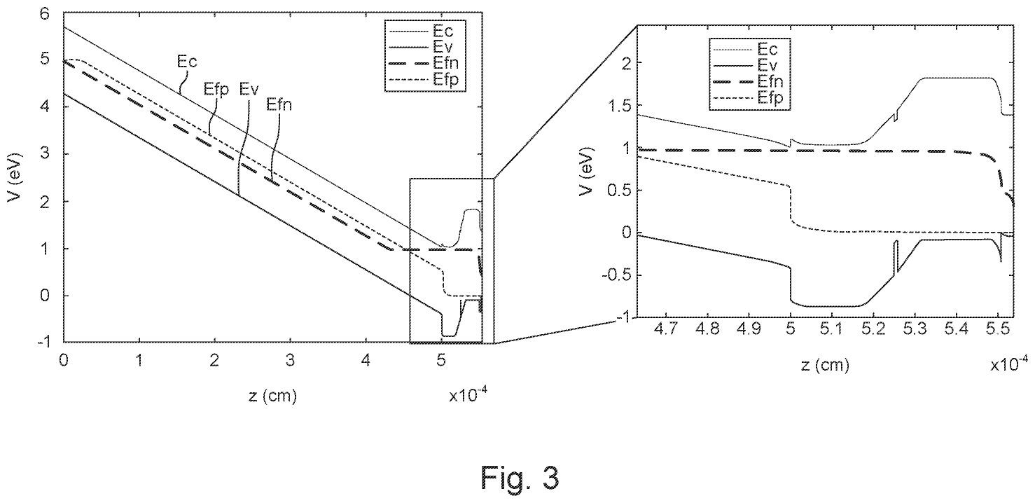

FIG. 3 shows the simulation results of the band diagram at a bias voltage of 5 V. The electric field (proportional to the gradient of E_{c} and Eᵥ) within bulk of this layer is uniform. Therefore, the device should behave similarly if the bias voltage is varied to keep the electric field equal with the increase of thickness of the GaAs layer. This GaAs layer can be a semi-insulating GaAs wafer or chromium compensated GaAs(GaAs:Cr) wafer. The simulation included the high resistivity of an idealized intrinsic GaAs layer. The contacts were assumed to be ohmic. Quantization effect on band structure were included.

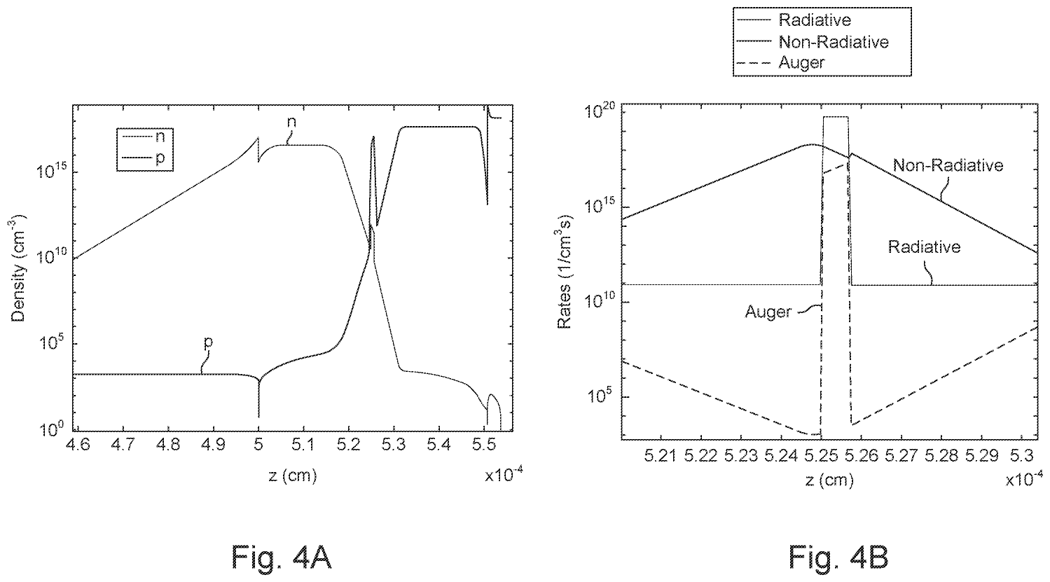

FIG. 4A shows simulated electron and hole concentrations at a bias voltage of 5 V. The hole concentration is much larger than electron concentration at the active QW region.

FIG. 4B shows the rates of different carrier recombination processes. At the active QW region, the radiative rate is much higher than other processes. This indicates a rather high internal quantum efficiency (IQE).

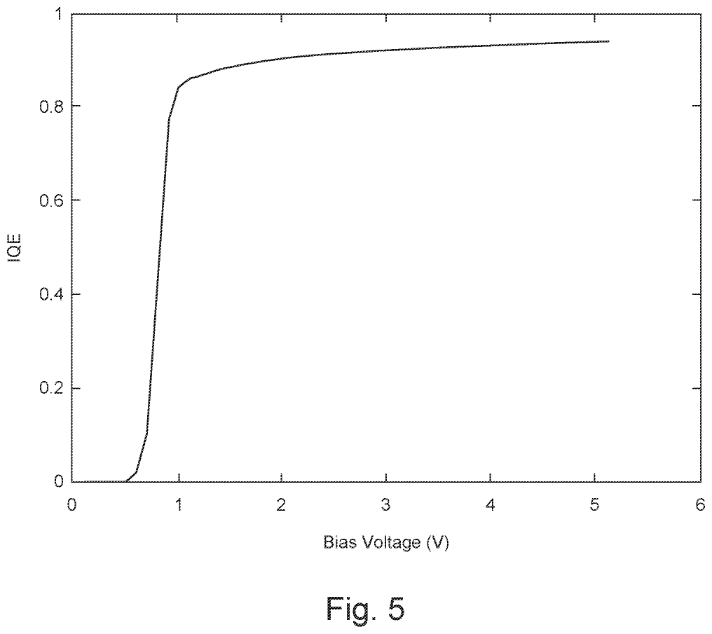

As shown in FIG. 5, when varying the forward bias voltage, the IQE is kept rather high when the bias voltage is more than about ˜1 V.

The above simulations were done without external x-ray or light to generate carriers in the detector region. To detect a signal, x-ray is illuminated onto the detector side to generate extra carriers. To simulate the extra carriers, a solar cell setting was employed to generate carriers within the detector region. The solar cell setting simulates illumination with infrared, visible or UV light. The difference between illuminating with visible light and x-ray is the distribution of the extra carriers. With x-ray, the carriers spread out across the thickness of the detector, while with visible light, the carriers concentrate near the front surface of the detector. After the carriers are generated, they drift towards the LED heterostructure 92.

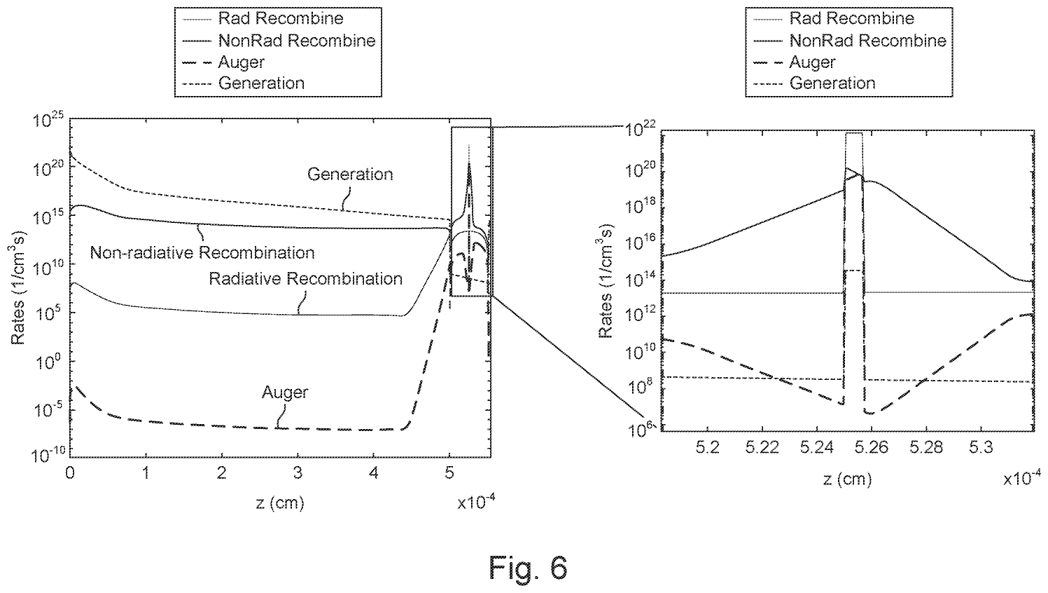

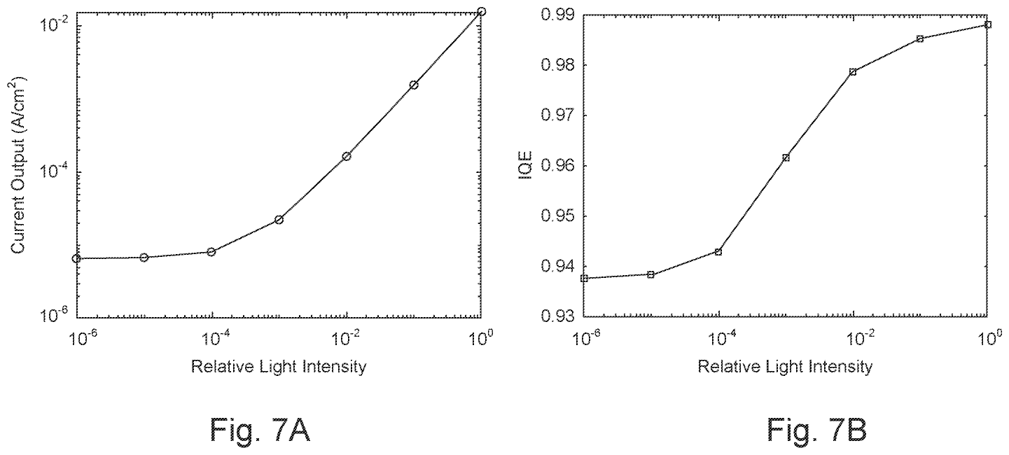

FIG. 6 shows rates of various processes, including the recombination rates and generation rate at a light intensity of 0.1 (relative to an arbitrary intensity as shown in FIGS. 7A and 7B). The generation was highest at z=0 as that was where the light entered the device. The relative positions of the 3 recombination rates were similar to those when no light was on. However, the absolute values were much larger because many extra carriers were generated at the z=0 and drifted to the LED. We also see a generation rate at the LED on this logarithm scale plot because there was small amount of the light penetrating the LED layers.

In the simulation, FIG. 7A shows the total current for the illumination light intensity to obtain the response of the device. The response was linear. However, there was a small offset due to the intrinsic conductivity of the GaAs detector layer. FIG. 7B shows that there was a small increase in IQE as light intensity increased, which can cause a small nonlinearity in the output light response to the light intensity. However, the change is rather small over a few decades of light intensity change, therefore the nonlinearity is small, making calibration easy.

The simulations showed that the above design of the detector/LED worked well with high IQE (>90%) at all light/x-ray exposure conditions. The biggest assumption is that the detector GaAs behaved like a pure intrinsic GaAs and the major trapping effects were ignored by the compensated trapping centers.

In another embodiment, the detector 12 uses single-crystalline CdTe or CdZnTe semiconductor detector layer 74 and CdTe or CdZnTe LED heterostructure 92. CdTe and CdZnTe has been studied for many years for x-ray and γ-ray detectors and they are two most widely used room-temperature semiconductor detector materials. They have larger mean atomic numbers than GaAs, therefore better stopping power than GaAs. And this makes them especially suitable for x-rays with energy higher than 10 keV.

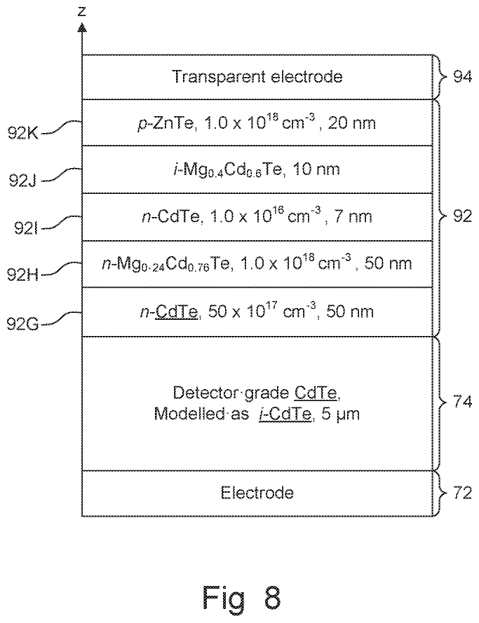

FIG. 8 shows a semiconductor LED x-ray detector using a CdTe material system.

The semiconductor detector layer 74 is a thick CdTe layer for detecting x-ray. The thick CdTe layer can be up to a few hundred microns thick. (Note, however, for simulation and illustration purposes, it is 5 μm.) It is located on the x-ray-side electrode layer 72.

The LED heterostructure layer 92 includes an n type CdTe layer dopant concentration 5.0×10¹⁷ cm⁻³, 92G of 50 nm thick, followed by an n-Mg_{0.24}Cd_{0.76}Te, 1.0×10¹⁸ cm⁻³, barrier layer 92H of 50 nm thick, followed by an n-CdTe, 1.0×10¹⁶ cm⁻³, active quantum well layer 92I of 7 nm thick, followed by an i-Mg_{0.4}Cd_{0.6}Te 10 nm barrier layer 92J, followed by a p-ZnTe, 1.0×10¹⁸ cm⁻³, contact layer 92K of 20 nm thick. The contact layer makes an electrical connection to the optical-side electrode layer 94.

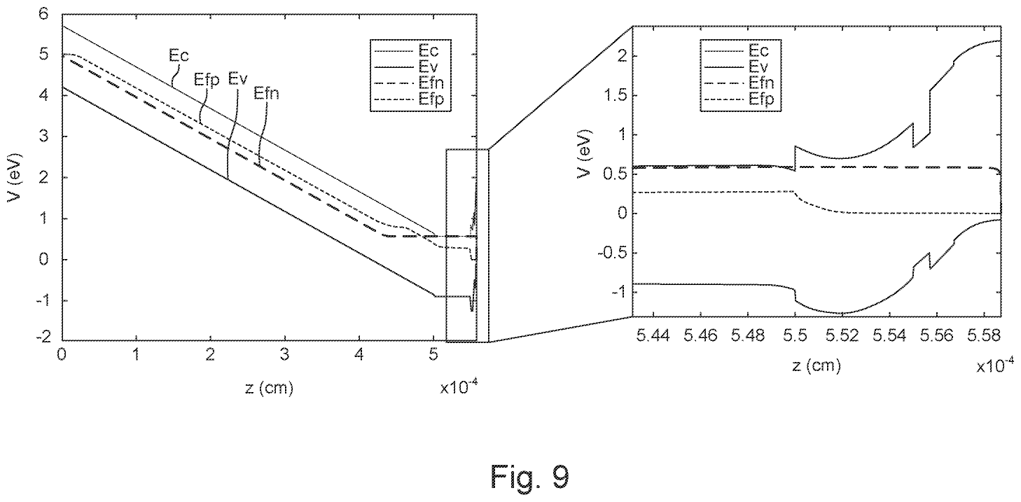

FIG. 9 shows the band diagram of the CdTe LED without external illumination at a bias voltage of 5 V. For the CdTe LED, at the QW region, the electron well was deeper than the hole well. And again, the electric field was constant in the bulk of the detector region.

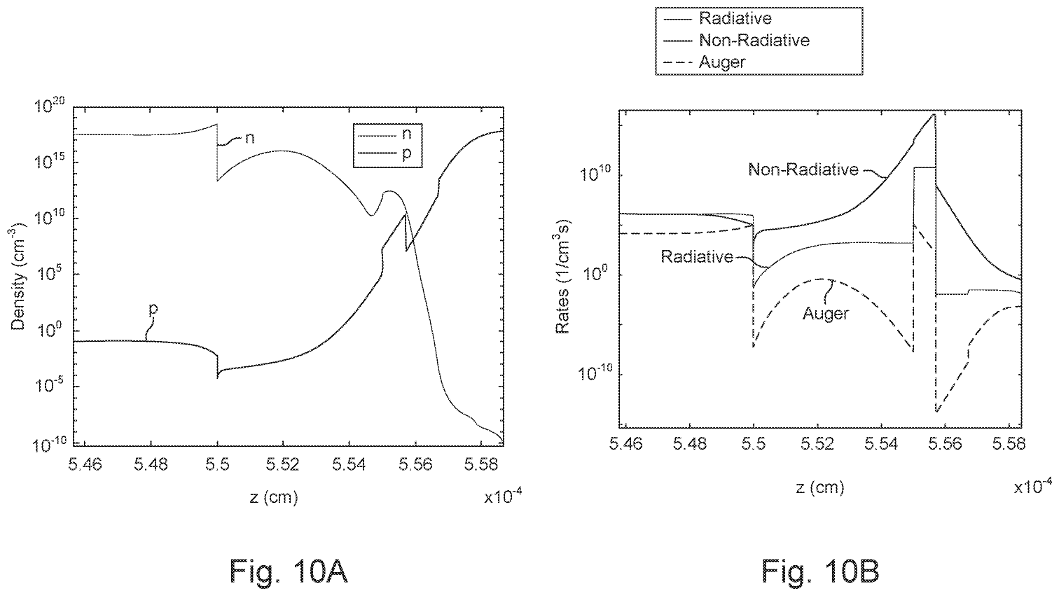

FIG. 10A shows the simulated electron and hole concentrations of the CdTe device at forward bias of 5V. At the active region, the electron concentration is much larger than the hole concentration. FIG. 10B shows the rates of different carrier recombination processes. At the active QW region, the non-radiative rate is much higher than other processes. This indicates that at 5V bias and no external illumination, the device will almost not emit light. This is not a problem for the detector because with external illumination, the device emit light.

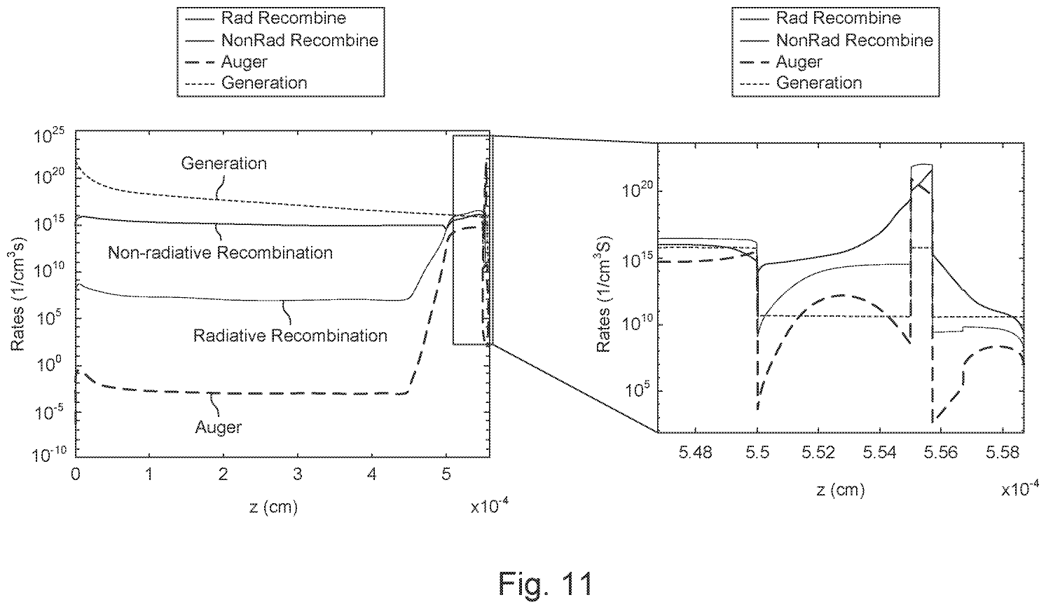

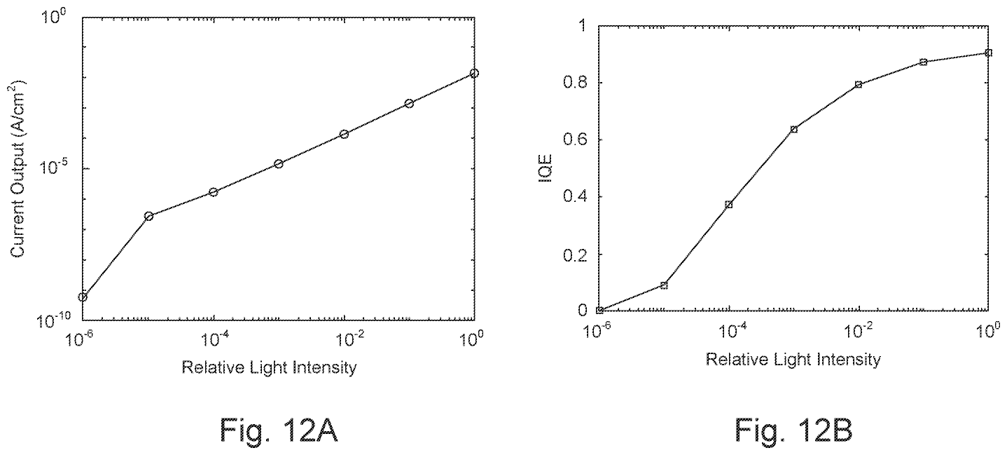

FIG. 11 shows rates of various processes, including the recombination rates and generation rate at a relative light intensity of 0.1 as in FIGS. 12A and 12B. With injected carriers from the external illumination, the radiative recombination rate increased.

The illumination light intensity was varied to obtain the response of the device. FIG. 12A shows the total current. FIG. 12B shows the IQE. IQE changes from 0 to around 0.9 at highest illumination. This will cause nonlinearity in the response. However, this simulation covered 6 orders of magnitude. In addition, the non-linearity can be calibrated. Lastly, the simulations treated the CdTe x-ray layer as an intrinsic semiconductor therefore carried a very low dark current at zero external illumination. The actual dark current is normally a few order magnitudes larger than the intrinsic value, this current will increase the IQE and make the IQE varies less over the different light intensities.

In another embodiment, the detector uses a perovskite semiconductor with the chemical formula ABX₃, such as CsPbBr₃, as an absorption semiconductor layer and an organic layer stack as LED. Similar to the inorganic LED device, the organic layer stack has several different layers for charge transport, charge injection or charge blocking around the emission layer. The emission layer itself includes different types of organic molecules, preferentially a phosphorescence emitter, such as Ir(ppy)₃ or a molecule allowing for thermally activated delayed fluorescence (TADF), such as 4CzIPN. OLEDs with the latter material have to be proven to exhibit a high IQE and a good linear response at different current densities, as well as a moderate lifetime of the excited state in the emitter molecule.

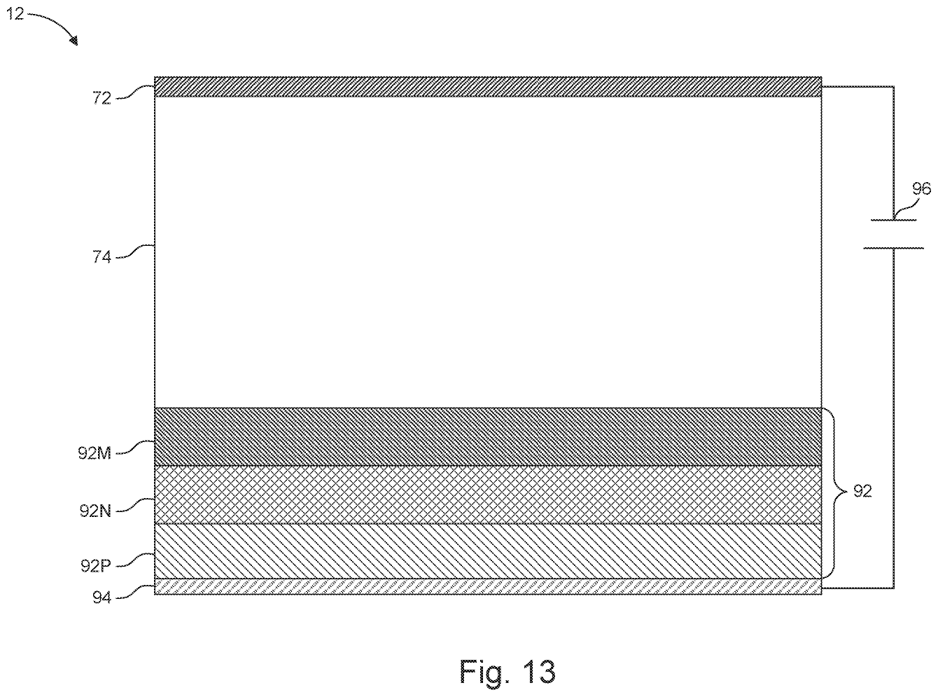

FIG. 13 shows a detector 12 using a combination of the perovskite absorbers and the organic layer stack.

The detector 12 comprises LED layer 92 disposed on one side of a CsPbBr semiconductor detector layer 74, which can be about 50 micrometers thick. A gold x-ray-side electrode layer 72 is deposited on an x-ray side of the semiconductor detector layer 74. On an optical-side of the semiconductor detector layer 74, is the OLED layer 92 followed by the transparent optical-side electrode layer 94 of indium tin oxide, for example.

OLED layer 92 include a TpBi layer 92M of about 65 nm, followed by a 4CziPN layer 92N of about 15 nm, followed by an Alpha-NPD layer 92P of about 35 nm.

To collect as much as possible light emitted from the LED (for both the inorganic LED or OLED), a few of the following measures can be taken separately or together:

When an air objective is used to collect the light, the highest possible NA should be employed for the selected magnification. However, with air objective, a lot of light will be lost. With a GaAs LED, the index of GaAs is about 3.6 at around 850 nm. The index mismatch with air is large. Without any other measures, most light will be trapped in the emission layer.

It is preferred a single layer or multiple layers of anti-reflective coating is applied onto the LED active layer. The transparent electrode material, ITO has an index close to the optimal index of 1.9 at 850 nm and can act as an antireflective coating with proper ITO receipt to fine tune the exact composition and processing to best match the anti-reflective conditions.

To further increase the NA of the objective, an immersion-type objective is preferred. The coupling of the LED with the objective can be a liquid, or an optical glue that fixes the LED with the objective. Because the objective focus onto the very thin LED active layer, no further adjustment is needed after it is focused, the glue option may be a preferred way in most cases.

A metalens may be used to replace expensive and bulky high-NA objective for light collection.

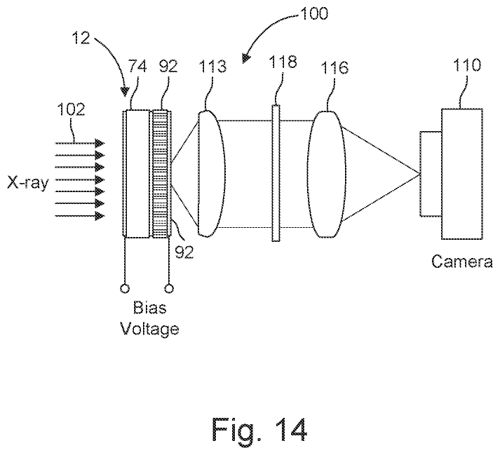

FIG. 14 shows a light optical microscope-based x-ray detection system 100 employing the detector 12.

In more detail, the x-ray detection systems 100 generally comprises the semiconductor LED x-ray detector 12. Incoming x-rays or charged particle beam 102 are received in the semiconductor layer 74. The resulting electric charges are injected into LED layer 92.

The light generated by the LED layer 92 is collected and collimated by objective lens 113. A tube lens provides the light to the camera 110. Another element 118 can be added in the infinity space to achieve other optional functions. For example, an x-ray shielding window to protect the tube lens 116 and the camera 110.

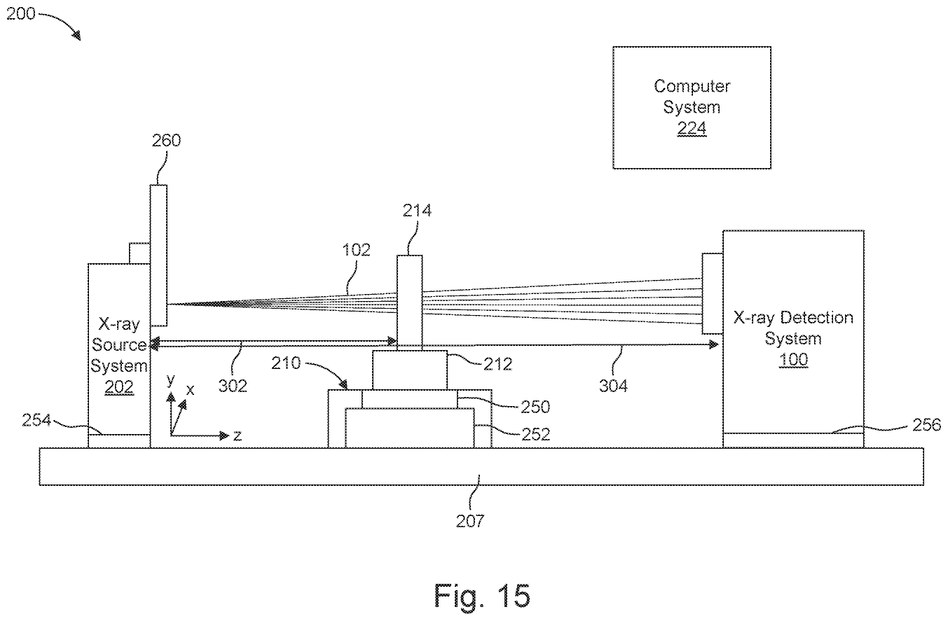

For context, FIG. 15 is a schematic diagram of an X-ray CT microscopy system 200 to which the x-ray detection system 100 and its semiconductor LED x-ray detector 12 are applicable.

Nevertheless, the present invention is applicable to charged particle analysis systems and non-microscopy systems.

The microscope 200 generally includes an X-ray imaging system that has an X-ray source system 202 that generates a polychromatic or possibly monochromatic X-ray beam 102 and an object stage system 210 with object holder 212 for holding an object 214 and positioning it to enable scanning of the object 214 in the stationary beam 102. The x-ray detection system 100 detects the beam 102 after it has been modulated by the object 214. A base such as a platform or optics table 207 provides a stable foundation for the microscope 200.

In general, the object stage system 210 has the ability to position and rotate the object 214 in the beam 102. Thus, the object stage system 210 will typically include a precision 3-axis stage 250 that translates and positions the object along the x, y, and z axes, very precisely but over relatively small ranges of travel. This allows a region of interest of the object 214 to be located within the beam 102. The 3-stage 250 is mounted on a rotation stage 252 that rotates the object 214 in the beam around the y-axis. The rotation stage 252 is in turn mounted on the base 107.

The source system 102 will typically be either a synchrotron x-ray radiation source or alternatively a “laboratory x-ray source” in some embodiments. As used herein, a “laboratory x-ray source” is any suitable source of x-rays that is not a synchrotron x-ray radiation source. Laboratory x-ray source 202 can be an X-ray tube, in which electrons are accelerated in a vacuum by an electric field and shot into a target piece of metal, with x-rays being emitted as the electrons decelerate in the metal. Typically, such sources produce a continuous spectrum of background x-rays combined with sharp peaks in intensity at certain energies that derive from the characteristic lines of the selected target, depending on the type of metal target used. Furthermore, the x-ray beams are divergent and lack spatial and temporal coherence.

In one example, source 202 is a rotating anode type or microfocused source, with a Tungsten target. Targets that include Molybdenum, Gold, Platinum, Silver or Copper also can be employed. Preferably a transmission configuration is used in which the electron beam strikes the thin target from its backside. The x-rays emitted from the other side of the target are used as the beam 102.

The x-ray beam generated by source 202 is preferably conditioned to suppress unwanted energies or wavelengths of radiation. For example, undesired wavelengths present in the beam are eliminated or attenuated, using, for instance, energy filters (designed to select a desired x-ray wavelength range (bandwidth)) held in a filter wheel 260. Conditioning is also often provided by collimators or condensers and/or an x-ray lens such as a zone plate lens.

When the object 214 is exposed to the X-ray beam 102, the X-ray photons transmitted through the object form a modulated x-ray beam that is received by the detection system 100. In some other examples, a zone plate objective x-ray lens is used to form an image onto x-ray detection system 100.

Typically, a magnified projection image of the object 214 is formed on the detection system 100. The magnification is equal to the inverse ratio of the source-to-object distance 302 and the source-to-detector distance 304.

Typically, the x-ray source system 202 and the detection system 100 are mounted on respective z-axis stages. For example, in the illustrated example, the x-ray source system 202 is mounted to the base 207 via a source stage 254, and the detection system 100 is mounted to the base 207 via a detector stage 256. In practice, the source stage 254 and the detector stage 256 are lower precision, high travel range stages that allow the x-ray source system 202 and detection system 100 to be moved into position, often very close to the object during object scanning and then be retracted to allow the object to be removed from, a new object to be loaded onto, and/or the object to be repositioned on the object stage system 210.

The operation of the system 200 and the scanning of the object 214 is controlled by a computer system 224 that often includes an image processor subsystem, a controller subsystem. The computer system is used to readout the optical image detected by the camera 110 of the detection system 100. The computer system 224, with the possible assistance of its image processor, accepts the set of images from the detection system 100 associated with each rotation angle of the object 214 to build up the scan. The image processor combines the projection images using a CT reconstruction algorithm to create 3D tomographic volume information for the object. The reconstruction algorithm may be analytical, where convolution or frequency domain filtering of the projection data is combined with back projection onto a reconstruction grid. Alternatively, it may be iterative, where techniques from numerical linear algebra or optimization theory are used to solve a discretized version of the projection process, which may include modeling of the physical properties of the imaging system.

While this invention has been particularly shown and described with references to preferred embodiments thereof, it will be understood by those skilled in the art that various changes in form and details may be made therein without departing from the scope of the invention encompassed by the appended claims.

1. A detection system, comprising:
a semiconductor layer for converting photons or particles into charge carriers; and
a light emitting layer for generating light from the charge carriers.

2. The detection system of claim 1, wherein the semiconductor layer coverts x-rays into the charge carriers.

3. The detection system of claim 1, wherein the semiconductor layer is amorphous selenium (a-Se), GaAs, CdZnTe, CdTe, or perovskite crystal (ABX3).

4. The detection system of claim 1, wherein the light emitting layer is an organic light emitting diode (OLED), GaAs, AlGaAs, InGaAs, CdTe or CdZnTe.

5. The detection system of claim 1, further comprising layers or structures that improve light outcoupling towards one or more detectors.

6. The detection system of claim 5, wherein the layers or structures include a reflective layer, a Bragg grating, a surface structure, and/or microlens between the semiconductor layer and the light emitting layer.

7. A detection method, comprising:
converting photons or particles into charge carriers in a semiconductor layer; and
generating light from the charge carriers.

8. The detection method of claim 7, wherein the semiconductor layer coverts x-rays into the charge carriers.

9. The detection method of claim 7, wherein the semiconductor layer is amorphous selenium (a-Se), GaAs, CdZnTe, CdTe, or perovskite crystal (ABX3).

10. The detection method of claim 7, further comprising improving light outcoupling towards one or more detectors.

11. The detection method of claim 10, further comprising improving the light outcoupling with a reflective layer, a Bragg grating, a surface structure, and/or microlens.

12. An x-ray microscopy system, comprising:
an x-ray source for generating an x-ray beam;
an object holder for holding an object in the x-ray beam; and
an x-ray detection system including a detector comprising a semiconductor layer for converting x-rays from the x-ray beam into charge carriers and a light emitting layer for generating light from the charge carriers, and a camera for detecting the light from the light emitting layer.

13. The x-ray microscopy system of claim 12, wherein the semiconductor layer is amorphous selenium (a-Se), GaAs, CdZnTe, CdTe, or perovskite crystal (ABX3).

14. The x-ray microscopy system of claim 11, wherein the light emitting layer is an organic light emitting diode (OLED), GaAs, AlGaAs, InGaAs, CdTe or CdZnTe.

15. The x-ray microscopy system of claim 12, further comprising layers or structures that improve light outcoupling toward the camera.

16. The x-ray microscopy system of claim 15, wherein the layers or structures include a reflective layer, a Bragg grating, a surface structure, and/or microlens between the semiconductor layer and the light emitting layer.
